(19) United States
(12) Patent Application Publication
(10) Pub. No.: US 2008/0238441 A1
(43) Pub. Date: Oct. 2, 2008

(54) Vector Network Analyzer-Noise Figure Measurement

(76) Inventors: Richard L. Rhymes, Santa Rosa, CA (US); John C. Faick, Santa Rosa, CA (US); Barry A. Brown, Santa Rosa, CA (US); Robert E. Shoulders, Santa Rosa, CA (US); Roger D. Pollard, Leeds (GB)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 11/694,571

(22) Filed: Mar. 30, 2007

(51) Int. Cl. G01R 29/26

(52) U.S. Cl. 324/601; 324/614

(57) ABSTRACT

A noise receiver is included in a network analyzer block diagram such that noise power and S-parameters measurements can be made almost simultaneously without mechanical switching in the test set. Additionally, a variable mismatch device tuner that is used by the network analyzer for S-parameter calibrations, is further used during the noise figure measurements method to remove the effect of source match variations so that the expected noise figure performance of the DUT when connected to a desired input (probably 50 ohms) can be determined.

### BACKGROUND

Noise figure measurements of active devices have always been a tedious, error prone procedure. By combining the noise figure receiver and a variable mismatch with the network analyzer, noise figure measurement accuracy is much improved and made significantly faster than before.

The mismatch and noise pulling of the device under test (DUT) as well as unaccounted for noise contributions of the noise measurement receiver are all major error sources in the measurement. Until now, to remove these errors, measurements from several test setups have been required. First, the DUT is measured with a network analyzer to characterize its S-parameters and then second the DUT is measured with a noise figure analyzer to obtain its noise figure. Plus, to account for the noise pulling of the amplifier due to input mismatch, the DUT is then re-measured with several known mismatch standards to determine the noise parameters of the device. These are time consuming measurements and especially tedious given that one is dealing with very small signal levels involved when measuring noise that are easily disrupted with manmade radiation present in the environment.

### SUMMARY

This invention combines the noise receiver into the network analyzer block diagram such that noise power and s-parameters measurements can be made almost simultaneously without mechanical switching in the test set. Additionally, a variable mismatch device know as E-cal, which is used by the network analyzer for S-parameter calibrations, is used during the noise figure measurements method to remove the effect of source match variations so that the expected noise figure performance of the DUT when connected to a desired input (probably 50 ohms) can be determined.

### BRIEF DESCRIPTION OF THE DRAWINGS

FIG. 1 illustrates a simplified block diagram of a prior art system for noise figure measurement.

FIG. 2 illustrates a simplified block diagram of the invention.

FIG. 3 illustrates a method of measurement according to the prior art.

FIG. 4 is a process flowchart for measurement using the apparatus shown in FIG. 2.

### DETAILED DESCRIPTION

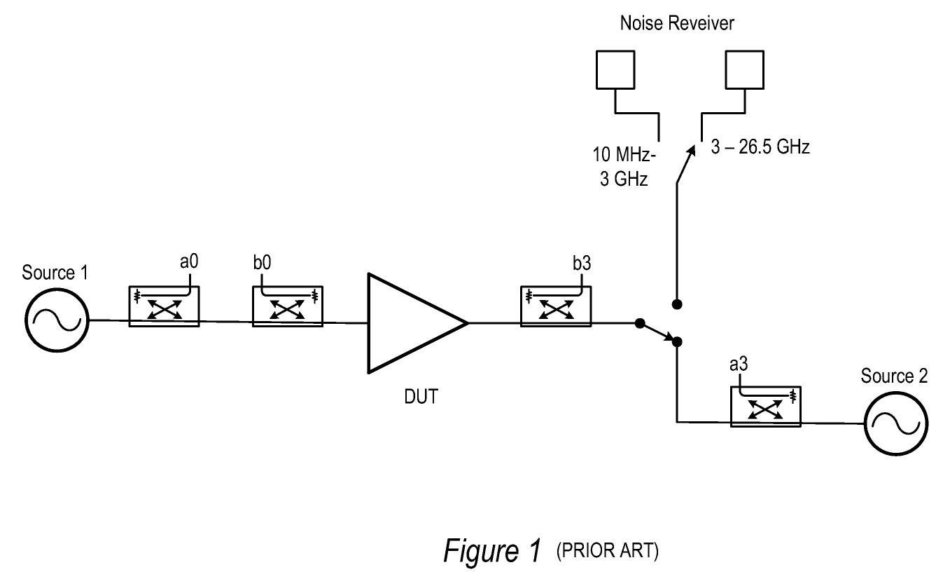

FIG. 1 illustrates a block diagram of the prior art.

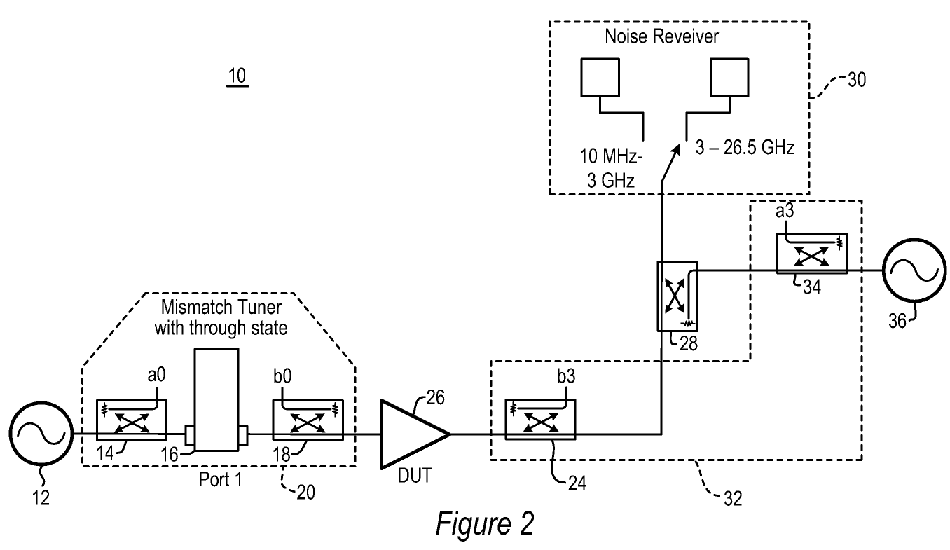

FIG. 2 illustrates a block diagram 10 of the invention. A first source 12 connects to a first directional coupler 14. A mismatch tuner 16 with a through state, (e.g. Ecal) is connected to a second directional coupler 18. These two couplers 14, 18 and the turner 16 implement the Port 1 reflectometer 20. The output of the Port 1 reflectometer connects to an input of a device under test (DUT) 26. A third directional coupler 24 connects to the output of the DUT 26. A fourth directional coupler 28 permits a direct low loss connection of the DUT 26 to a low noise receiver 30 for noise power measurements while additionally providing a path to the reference directional coupler 34 of a second source 36. The third and fifth directional couplers 24, 34 form the reflectometer of Port 2 32.

Although the mismatch tuner is shown positioned within the Port 1 reflectometer, it may also be positioned before or after the first and second directional couplers.

The noise receiver may be connected to any one of the third, fourth, and fifth directional couplers. The fourth directional coupler may be replaced by a switch. When a switch is used, it may be positioned before or after the third and fifth directional couplers.

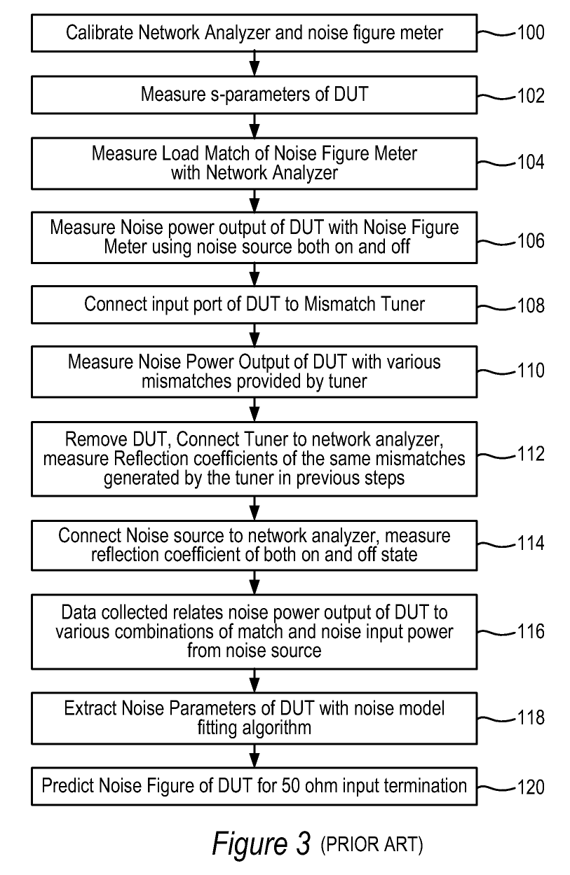

FIG. 3 illustrates a process flowchart corresponding to a prior art method of performing a noise parameter extraction using several different instruments.

In step 100, the network analyzer and the noise figure meter are calibrated.

In step 102, the S parameters of the DUT are measured.

In step 104, the load match of the noise figure meter is measured with the network analyzer.

In step 106, the noise figure meter measure the noise power output of the DUT with the noise source on and off.

In step 108, the input port of the DUT is connected to the mismatch tuner.

In step 110, the noise power output of the DUT with various mismatches provided by the tuner is measured.

In step 112, the DUT is removed. The mismatch tuner is connected to the network analyzer. The reflection coefficients of the same mismatches generated by the tuner in the previous steps are measured.

In step 114, the noise source is connected to the network analyzer. The reflection coefficients are measured while the noise source is on and off.

In step 116, data is collected that relates to the noise power output of the DUT to various combinations of match and noise input power from the noise source.

In step 118, the noise parameters of the DUT are extracted using a noise model fitting algorithm.

In step 120, the noise figure of the DUT is predicted for a 50 ohm input termination.

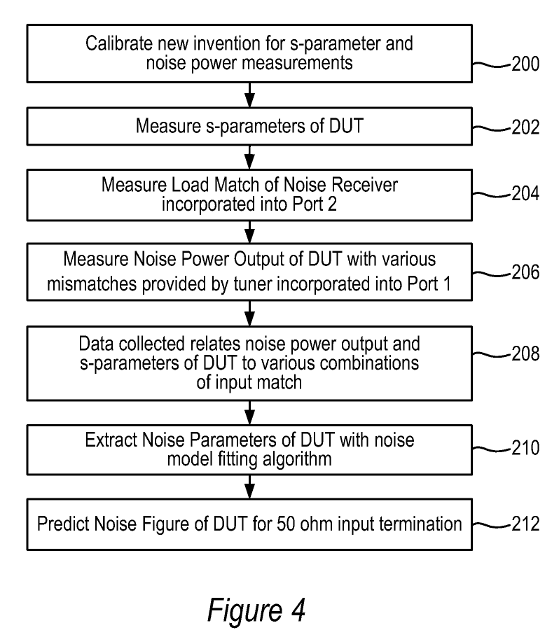

FIG. 4 illustrates noise parameter extraction using the apparatus shown in FIG. 2.

In step 200, the apparatus is calibrated for S-parameter and noise power measurements

In step 202, the S-parameters of DUT are measured.

In step 204, the Load Match of Noise Receiver incorporated into Port 2 of the apparatus is measured.

In step 206, the Noise Power Output of DUT with various mismatches provided by tuner incorporated into Port 1 of the apparatus is measured.

In step 208, data is collected that relates noise power output and s-parameters of DUT to various combinations of input match.

In step 210, Noise Parameters of DUT with noise model fitting algorithm are extracted.

In step 212, the Noise Figure of DUT for 50 ohm input termination is predicted.

We claim:

1. An instrument for measuring a device under test comprising:
a first source;
a port 1 reflectometer, connected to the first source, including two serially connected directional couplers;
a mismatch tuner, having a through state, connecting the port 1 reflectometer;
a port 2 reflectometer including,
a first and a second directional coupler, and
one of a switch and a third directional coupler interposing the first and the second directional couplers;
wherein the device under test interposes the port 1 and the port 2 reflectometers;
a low noise receiver connecting the port 2 reflectometer; and
a second source connecting the port 2 reflectometer.

2. An instrument as in claim 1, the mismatch tuner is an ECal.

3. An instrument as in claim 1, wherein the mismatch tuner interposes the first source and the port 1 reflectometer.

4. An instrument as in claim 1, wherein the mismatch tuner interposes the two serially connected directional couplers.

5. An instrument as in claim 1, wherein the mismatch tuner interposes the port 1 reflectometer and the device under test.

6. A method comprising:
calibrating an instrument for S-parameter and noise power measurements;
measuring S-parameters of a device under test (DUT);
measuring the load match of a noise receiver incorporated into Port 2 of the instrument;
measuring the noise power output of the DUT with various mismatches provided by mismatch tuner incorporated into Port 1 of the instrument;
collecting data relating noise power output and s-parameters of the DUT to various combinations of input match;
extracting noise parameters of the DUT; and
predicting the noise figure of the DUT.

7. A method as in claim 6, the instrument comprising:
a first source;
a port 1 reflectometer, connected to the first source, including two serially connected directional couplers;
a mismatch tuner, having a through state, connecting the port 1 reflectometer;
a port 2 reflectometer including,
a first and a second directional coupler, and
one of a switch and a third directional coupler interposing the first and the second directional couplers;
wherein the device under test interposes the port 1 and the port 2 reflectometers;
a low noise receiver connecting the port 2 reflectometer; and
a second source connecting the port 2 reflectometer.

8. A method as in claim 7, the mismatch tuner is an ECal.

9. A method in claim 7, wherein the mismatch tuner interposes the first source and the port 1 reflectometer.

10. An instrument as in claim 7, wherein the mismatch tuner interposes the two serially connected directional couplers.

11. An instrument as in claim 7, wherein the mismatch tuner interposes the port 1 reflectometer and the device under test.

12. A method as in claim 5, predicting the noise figure of the DUT is for a 50 ohm input termination.
